(19) United States
(12) Patent Application Publication
(10) Pub. No.: US 2026/0018449 A1
(43) Pub. Date: Jan. 15, 2026

(54) SUBSTRATE PROCESSING APPARATUS

(71) Applicant: NISSIN ION EQUIPMENT CO., LTD., Koka-city (JP)

(72) Inventors: Shinsuke INOUE, Koka-city (JP); Takayuki MURAYAMA, Koka-city (JP); Yuya HIRAI, Koka-city (JP)

(73) Assignee: NISSIN ION EQUIPMENT CO., LTD., Koka-city (JP)

(21) Appl. No.: 19/261,100

(22) Filed: Jul. 7, 2025

(30) Foreign Application Priority Data
Jul. 12, 2024 (JP) 2024-112099

(51) Int. Cl. H01L 21/683; H01J 37/32

(52) U.S. Cl. CPC H01L 21/6833; H01J 37/32715; H01J 2237/2007

(57) ABSTRACT

A substrate processing apparatus includes an electrostatic chuck that supports a substrate, a detachment device that releases the substrate that is supported by the electrostatic chuck, from the electrostatic chuck, and a control device that determines a load on the detachment device and applies a release voltage to the electrostatic chuck, based on the load.

### CROSS REFERENCE TO RELATED APPLICATIONS

This application is based on and claims priority from Japanese Patent Application No. JP2024-112099 filed on Jul. 12, 2024 in the Japan Patent Office, the contents of which being incorporated by reference herein in its entirety.

### BACKGROUND

### 1. Field

The present disclosure relates to a substrate processing apparatus equipped with an electrostatic chuck.

### 2. Description of Related Art

In a substrate processing apparatus such as a film deposition apparatus, a dry etching apparatus, and an ion implantation apparatus, substrates are subjected to prescribed processing while being supported by an electrostatic chuck. After the substrate processing is completed, the substrate is released from the electrostatic chuck, transported on a predetermined route and stored in a cassette or other container.

### SUMMARY

According to an aspect of one or more embodiments, there is provided a substrate processing apparatus comprising an electrostatic chuck that is configured to support a substrate; a detachment device that is configured to release the substrate that is supported by the electrostatic chuck, from the electrostatic chuck; and a control device that determines a load on the detachment device and applies a release voltage to the electrostatic chuck, based on the load.

According to another aspect of one or more embodiments, there is provided a substrate processing apparatus comprising an electrostatic chuck that is configured to support a substrate; a control device that applies a release voltage to the electrostatic chuck; and a drive source that is configured to rotate the electrostatic chuck to release the substrate that is supported by the electrostatic chuck, from the electrostatic chuck. The control device determines a load on the drive source based on an output signal from the drive source, determines whether the load is greater than a reference value, and when the load is greater than the reference value, increases the release voltage.

According to yet another aspect of one or more embodiments, there is provided a substrate processing apparatus comprising a platen comprising an electrostatic chuck that is configured to support a substrate; a drive source that is configured to move the platen; and a control device that applies a release voltage to the electrostatic chuck and controls the drive source to move the platen to physically release the substrate that is supported by the electrostatic chuck, from the electrostatic chuck. The control device determines a load caused by a movement of the platen to physically release the substrate, determines whether the load is greater than a reference value, and when the load is greater than the reference value, increases the release voltage

### BRIEF DESCRIPTION OF THE DRAWINGS

The above and/or other aspects will become apparent and more readily appreciated from the following description of various embodiments, taken in conjunction with the accompanying drawings, in which:

FIG. 1 illustrate a schematic configuration diagram of a substrate processing apparatus, according to some embodiments;

FIG. 2 illustrates an example of a state of a platen during a transfer of the substrate, according to some embodiments;

FIG. 3 shows a posture of the platen 2 of FIG. 2 during delivery of a substrate, according to some embodiments;

FIG. 4 illustrates an example of a substrate removal operation, according to some embodiments;

FIG. 5 illustrates a view of the substrate removal operation of FIG. 4 from an ZX plane, according to some embodiments;

FIG. 6 illustrates a diagram explaining the substrate removal operation, according to some embodiments;

FIG. 7 illustrates a diagram explaining the substrate removal operation, according to some embodiments;

FIG. 8 illustrates a relationship between removal voltage and adsorption voltage, according to some embodiments;

FIG. 9 illustrates a flowchart illustrating substrate removal method, according to some embodiments; and

FIG. 10 illustrates a schematic configuration diagram of a substrate processing apparatus, according to some embodiments.

### DETAILED DESCRIPTION

Hereinafter, various embodiments of the present disclosure will be described with reference to the drawings. In all the drawings for explaining the various embodiments, common components are denoted by the same reference numerals, and repeated description thereof will be omitted for conciseness. The following embodiments do not unduly limit the contents of the present disclosure described in the appended claims. Further, all the components shown in the embodiments are not necessarily essential components of the present disclosure. Each drawing is a schematic view and is not necessarily intended to illustrate various dimensions strictly.

After the substrate processing described above, a release voltage is applied to the electrostatic chuck to remove a residual charge that is generated between the substrate and the electrostatic chuck in response to the substrate being released from the electrostatic chuck.

The residual adsorption force generated by the residual charge does not disappear instantaneously upon application of the release voltage, but the residual adsorption force decreases over time after application of the release voltage.

If a substrate is forcibly released from the electrostatic chuck while a relatively large residual adsorption force remains, various disadvantages such as cracking, bouncing, and movement of the substrate will occur. If the elapsed time after the release voltage is applied is set sufficiently long, the residual adsorption force can be reduced. However, in this case, productivity of the substrate processing apparatus will be reduced.

A related art technology proposes to release the substrate from an electrostatic chuck at an appropriate timing based on measurement results from various sensors. Specifically, multiple laser displacement sensors and capacitance sensors are installed facing the surface of a substrate in the substrate release direction, and a state of substrate adsorption is monitored using these sensors. Based on the monitoring results of the adsorption state, the substrate is released from the electrostatic chuck at a timing at which the adsorption state becomes suitable for substrate release.

However, the substrate adsorbed on the electrostatic chuck is not completely flat. For example, the substrate surface may contain minute irregularities, or the substrate surface may be slightly inclined. In addition, the temperature characteristics of the substrate to be handled and the temperature characteristics of the electrostatic chuck supporting the substrate make the temperature distribution within the substrate surface non-uniform. As a result, local distortion occurs within the substrate surface, and there is concern that this distortion may cause warping of the substrate. Especially, a substrate processing apparatus that performs high-temperature processing of substrates tends to cause large warping of the substrates.

If the substrate is greatly warped, some portions may contact the electrostatic chuck and may be supported by the electrostatic chuck and other portions may not contact the electrostatic check and may not be supported by the electrostatic chuck within the entire substrate surface. In this case, the substrate and the electrostatic chuck are partially in contact, and only the contacting area is adsorbed by the electrostatic chuck.

If the substrate is supported in this manner, the method of the related art, in which the adsorption state between the substrate and the electrostatic chuck is monitored by a sensor, may result in misjudgment of the adsorption state. Even if the substrate as a whole is generally absorbed to the electrostatic chuck (i.e., the substrate as a whole is only partially adsorbed at the contacting area), if the part of the substrate facing the sensor is not in contact with the electrostatic chuck, the substrate is misjudged as being detached from the electrostatic chuck.

To avoid such misjudgments, the number of sensors could be increased, but this increase would cause various disadvantages, such as increased costs due to additional sensors, limited locations for sensor placement, and complexity of signal processing.

In another related art technology, a method is proposed in which a force sensor is mounted on a push-up pin used at the time of substrate release, and the state of substrate adsorption is determined from a measurement result of a load applied to the force sensor. Specifically, after stopping a voltage applied to the electrostatic chuck to absorb the substrate, the push-up pin is raised, and the adsorption state of the substrate is determined based on the load measured by the force sensor. In the related art, the state of substrate adsorption is determined by physically pressing the substrate, so even if the substrate is partially supported by the electrostatic chuck, the state of substrate adsorption can be determined correctly.

In this related art technology, it is proposed to reduce the residual adsorption force by slightly pushing the substrate edge up from the electrostatic chuck using the push-up pin after the adsorption voltage is stopped. However, in a case in which the substrate edge from the electrostatic chuck is released while most of the substrate is absorbed to the electrostatic chuck by the residual adsorption force, it is necessary to apply a large force to the substrate edge at the initial push-up. There is a disadvantage in that such a large force to push up the edge of the substrate may cause damage to the edge of the substrate. Various embodiments discussed below address these and other disadvantages.

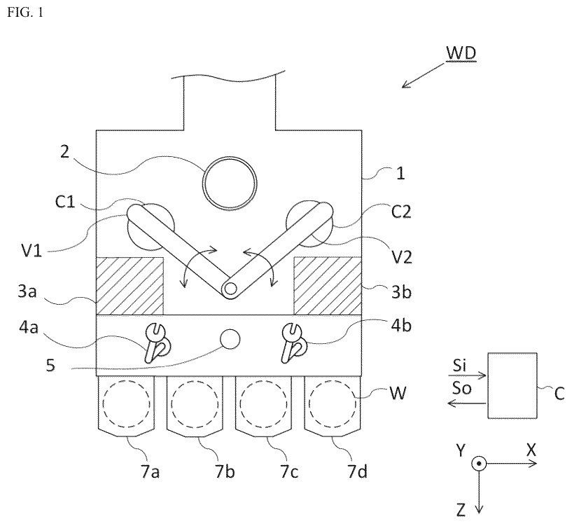

FIG. 1 illustrate a schematic configuration diagram of a substrate processing apparatus, according to some embodiments. For example, FIG. 1 shows a configuration around a processing chamber in an ion implantation apparatus as an example of a substrate processing apparatus WD. A plurality of substrates W are stored in cassettes 7a-7d. The substrate W may be a substrate with a flat circular outer shape, may be made of SiC, Si, GaN or Ga₂O₃, and may have a notch, orifler, or other marker on an outer circumference to mark a reference position. However, embodiments are not limited to the type and shape of substrate W described above. For example, in some embodiments, the substrate W may be a glass substrate with a rectangular plan view.

Atmospheric robots 4a and 4b pick up the substrate W from cassettes 7a-7d and transfer the substrate W to aligner 5. After the circumferential position of substrate W is adjusted in aligner 5, atmospheric robots 4a and 4b transfer the substrate W to load-lock chambers 3a and 3b. The load-lock chambers 3a and 3b allow substrate transfer between a processing chamber 1 and the chamber where the aligner 5 is located by switching the vacuum level in the load-lock chambers 3.

The floors of the load-lock chambers 3a and 3b are moved in a direction parallel to the Y axis by an unshown drive structure. The floor movement is performed after the load-lock chambers 3a and 3b are switched from air to vacuum.

The process chamber 1 includes vacuum hands V1 and V2 that can swivel independently in a direction of arrows shown in FIG. 1. The vacuum hands V1 and V2 are equipped with gripping portions C1 and C2 that grip the substrate W. The vacuum hands V1 and V2 grasp the substrates W in the load-lock chambers 3a and 3b and transfer the substrates W to a platen 2.

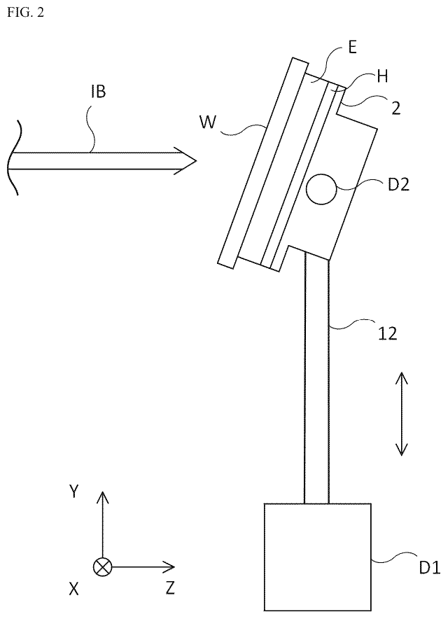

FIG. 2 illustrates an example of a state of a platen during a transfer of the substrate, according to some embodiments. For example, FIG. 2 shows an ion implantation process being performed to a substrate W supported on the platen 2. A drive shaft 12 reciprocates the platen 2 along the Y-axis direction by a drive source D1 (e.g., a scan motor). The ion beam IB shown in FIG. 2 may be a spot-shaped ion beam in the XY plane. The ion beam IB is scanned in a direction parallel to the X axis direction by electrostatic or magnetic fields. The scanning width of the ion beam IB may be larger than a diameter of the substrate W.

The platen 2 includes an electrostatic chuck E that adsorbs and supports the substrate W. In some embodiments, the platen 2 may include a heater H that heats the substrate W to a high temperature during substrate processing.

The substrate W, which is adsorbed and supported by the electrostatic chuck E, is adjusted in the circumferential direction of the substrate W by an unshown twist structure. The drive source D2 (e.g., a tilt motor) that drives the tilt structure (not shown) rotates the platen 2 around an axis parallel to the X axis, and the irradiation angle of the ion beam IB to the substrate W may be adjusted.

After the platen 2 posture is adjusted, the drive shaft 12 reciprocates, causing the surface of the substrate W to move across the ion beam IB, and the ion implantation process to the substrate W is performed.

Instead of the ion beam IB described above, in some embodiments, a ribbon-shaped ion beam with a rectangular cross portion in the XY plane may be used. In this case, a dimension of the ion beam IB may be larger than the diameter of the substrate W in the X-axis direction. If such ribbon beam is used, scanning of the ion beam IB in the direction parallel to the X-axis becomes unnecessary.

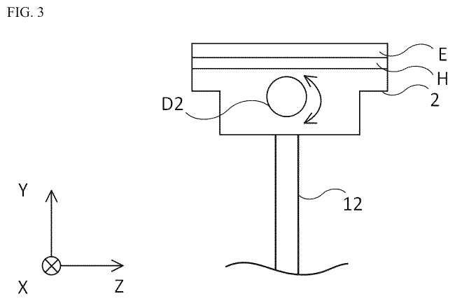

FIG. 3 shows the posture of platen 2 during the delivery of substrate W, according to some embodiments. During transportation of the substrate W to the platen 2 or from the platen 2, the drive source D2 rotates the platen 2, and the platen 2 posture becomes horizontal. The drive source D2 illustrated in FIGS. 2 and 3 is configured to rotate the platen 2 around an axis parallel to the X axis. However, in some embodiments, the driver source D2 can also be configured to rotate the platen 2 around an axis parallel to the Y axis. In that case, another drive source may be provided to make the platen 2 posture horizontal to transport the substrate W.

The configuration of the ion implanter described in FIGS. 1-3 is an example and embodiments are not limited to the configuration depicted in FIGS. 1-3. For example, the number of vacuum hands V1, V2, load-lock chambers 3a, 3b, atmospheric robots 4a, 4b, and cassettes 7a-7d is not limited to the numbers illustrated in FIGS. 1-3. In some embodiments, the numbers may be configured to provide one of each.

Returning to FIG. 1, the substrate processing apparatus WD may include a control device C. In an embodiment, the control device C may control various components of the substrate processing apparatus WD. For example, in an embodiment, the control device C may control the vacuum hands V1, V2, the load-lock chambers 3a, 3b, the atmospheric robots 4a, 4b, the cassettes 7a-7d, the drive source D1, and the drive source D2. In an embodiment, the control device C may include a memory to store data and a processing circuit to calculate the data. The processing circuit may include one or more processors, central processors, microprocessors, microcontrollers, and/or hardware control logic.

In an embodiment, the control device C may control the drive source D1 and/or the drive source D2 to move the platen 2 to physically release the substrate W that is supported by the electrostatic chuck E, and to apply the release voltage to the electrostatic chuck E, as described in more detail below. When the substrate W is released from the electrostatic chuck E, a signal Si related to the adsorption state of the substrate W is input to the control device C. The control device C refers to reference state data corresponding to a reference state that is stored in the control device C (e.g., stored in the memory of the control device C) and compares the adsorption state with the reference state indicated by the reference state data, and determines whether the adsorption state is equal to or less than the reference state. If the adsorption state is not equal to the reference state, the control device C outputs a signal So to change a release voltage.

More specifically, in an embodiment, the signal Si may be the load applied to a detachment device F, which is described below. The control device C stores a load value at which the substrate W can be released as a reference value. The control device C compares the reference value with the load applied to the detachment device F. If the load applied to the detachment device F is less than the reference value, the detachment operation of the substrate W by the detachment device Fis continued. Conversely, if the load exceeds the reference value, the control device C outputs the signal So to increase the value of the release voltage.

In an embodiment, the reference state may be a state in which the substrate W is adsorbed and supported by the electrostatic chuck E to the extent that various defects such as bouncing or cracking of the substrate W due to a residual adsorption force do not occur when the substrate W is released from the electrostatic chuck E. The value of the load applied to the detachment device F when such a reference state is achieved may be determined in advance by experiment and stored in the control device C.

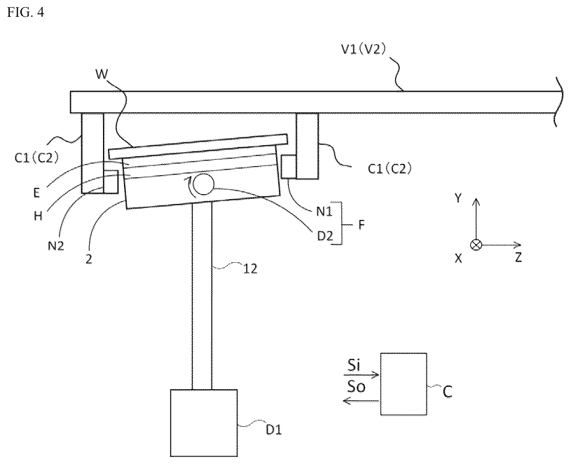

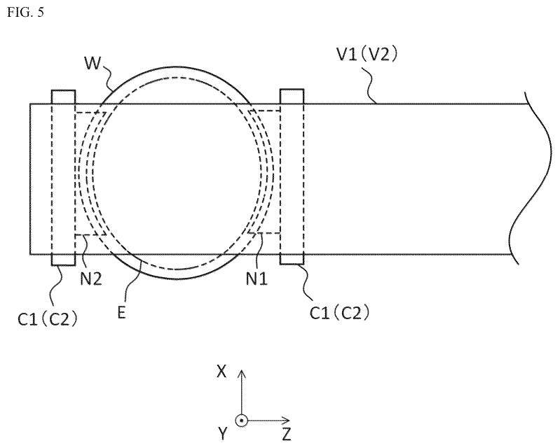

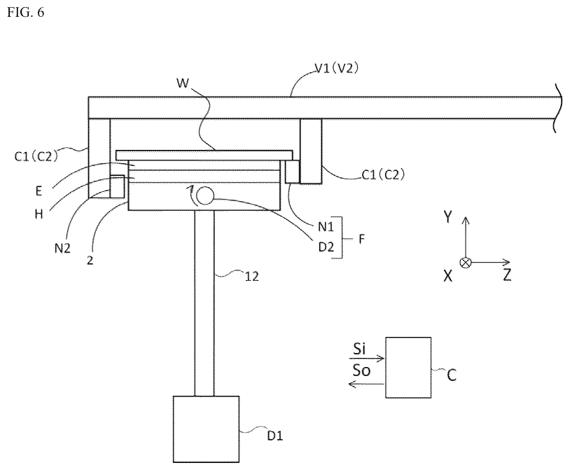

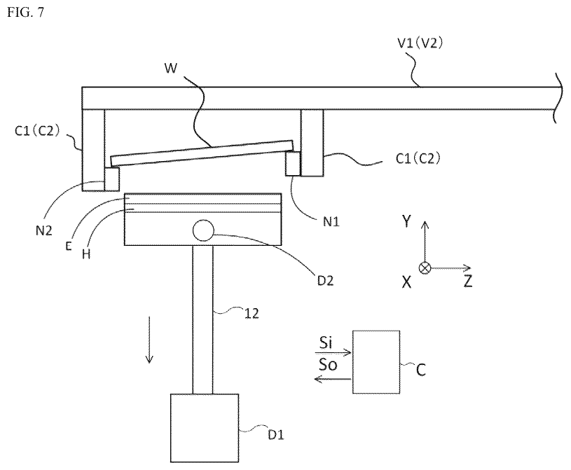

FIGS. 4, 6, and 7 show a substrate release operation, according to some embodiments. The substrate release operation is performed in the order of FIG. 4, FIG. 6, and FIG. 7. FIG. 5 is a plan view of FIG. 4 from the ZX plane. When the vacuum hand V1 (V2) is viewed from above, as illustrated in FIG. 5, components depicted by dashed lines are hidden by the vacuum hand V1 (V2) and substrate W.

After substrate processing, the platen 2 moves downward while maintaining a slightly inclined posture. The vacuum hand V1 (V2) then swivels to a position of platen 2, as illustrated in FIGS. 4 and 5.

The vacuum hand V1 (V2) has a pair of gripping portions C1 (C2) that extend downward. The gripping portions C1 (C2) are spaced apart from each other with a gap. By swiveling the vacuum hand V1 (V2) to the platen 2 position, the platen 2 is placed between the gripping portions C1 (C2) of the vacuum hand V1 (V2).

The gripping portions C1 (C2) have a first claw N1 and a second claw N2. Since the length of each gripping portion C1 (C2) from the vacuum hand V1 (V2) is different, the attachment positions of the claw N1 and the claw N2 in the Y-axis direction are different. Specifically, in an embodiment, the claw N1 may be located slightly higher than the claw N2 in the Y-axis direction as illustrated in FIG. 4.

In the embodiments shown in FIGS. 4-7, the detachment device F for releasing the substrate W from the electrostatic chuck E may include the claw N1 and the drive source D2.

As described above, in an embodiment, the control device C may control the drive source D1 and/or the drive source D2 to move the platen 2 to physically release the substrate W that is supported by the electrostatic chuck E. For example, the platen 2 shown in FIG. 4 is rotated clockwise by drive source D2 to the state shown in FIG. 6. In FIG. 6, the claw N1 is in contact with the edge of the substrate W and prevents further movement rotation of the drive source D2 in a clockwise direction. When the platen 2 is in this state, a load is applied to the drive source D2 by the continued clockwise rotation of the platen 2 by the drive source D2. For example, in an embodiment, the load may be a load or force on the drive source D2 that resists a further rotation of the drive source D2 in the clockwise direction. For example, in an embodiment, the load may be a force applied by the claw N1 to the drive source D2 through the substrate W as the drive source D2 rotates the platen 2 clockwise. In some embodiments, the load may be a current of the drive source D2 that is output as an output signal from the drive source D2. For example, as the drive source D2 continues to rotate the platen 2 clockwise, the torque increases due to strong chucking by the electrostatic chuck E (i.e., a load by the substrate is high), and the increasing torque of the drive source D2 makes a current of drive source D2 increase. As a result, an output signal corresponding to the current of the drive source D2 becomes high. Based on a measurement result of the load, the control device C determines the adsorption state of the substrate W. In an embodiment, the load may be measured when a torque for continued rotation of the platen 2 by the drive source D2 has become constant.

In an embodiment, an initial load on the drive source D2 when the claw N1 contacts the edge of the substrate W is a relatively large load. The load on the drive source D2 converges to a nearly constant value after a few seconds. The value of the load when the load has converged to the constant value is used by the control device C to determine the adsorption state of the substrate W. In an embodiment, the load on the drive source D2 may be measured by reading an output signal of the drive source D2. The same applies to the measurement of the load applied to the drive source D1, described later.

When the substrate W is physically released by the detachment device F, specifically, after the edge of the substrate W is pressed against the claw N1, the control device C applies a release voltage to the electrostatic chuck E.

In an embodiment, the release voltage may be a voltage that cancels the residual charge remaining between the substrate W and the electrostatic chuck E. For example, in an embodiment, the release voltage may be a voltage of the same polarity as the adsorption voltage applied to the electrostatic chuck during substrate processing, and may be a voltage about 30% larger than the adsorption voltage. In some embodiments, the release voltage may be a voltage of an opposite polarity to the adsorption voltage applied to the electrostatic chuck during substrate processing and may be a voltage less in magnitude than the adsorption voltage.

If no release voltage is applied, the force required to release the edge of the substrate W from the electrostatic chuck E is large. However, since the application of the release voltage reduces the residual adsorption force acting on the substrate W, the force to release the edge of the substrate W from the electrostatic chuck E can be reduced. As a result, the risk of damage to the edge of the substrate can be reduced at the time of substrate release.

After the platen 2 is rotated to release the substrate W from the electrostatic chuck E as illustrated in FIG. 6, the platen 2 is moved downward as shown in FIG. 7. By moving the platen 2 downward, the substrate W is transferred onto the claw N1 and the claw N2.

It is noted that the configuration of the detachment device F may correspond to a configuration in which the substrate W is to be released. As described above, in the embodiments shown in FIGS. 4-7, the detachment device F for releasing the substrate W from the electrostatic chuck E includes the claw N1 and the drive source D2 and the drive source D2 rotates clockwise as shown in FIG. 4. However, in some embodiments, the drive source D2 may rotate counterclockwise and, in this case, the claw N2 may be disposed lower than the claw N1, the detachment device F may include the claw N2 and the drive source D2, and the load may be a load on the drive source D2 by a force applied by the claw N2 to the drive source D2 through substrate W as the drive source D2 rotates the platen 2 counterclockwise.

Since the control device C is configured to determine the adsorption state of substrate W based on the load on the detachment device F, it is possible to accurately determine the adsorption state of substrate W even when large warping of substrate W occurs due to high-temperature processing.

In the determination of the adsorption state by the control device C, if the current adsorption state does not equal the reference state, the release voltage applied to the electrostatic chuck E is changed to a larger value. The value of the release voltage that is set and described here is an absolute value.

By changing the value of the release voltage that is set, it is possible to actively reduce the residual charge and shorten the time to release the substrate W.

The value of the release voltage that is set may be set to a relatively large value from the initial stage. However, there is concern that the application of a large release voltage may cause the residual charge to dissipate in a very short period of time and the substrate W may be reabsorbed to the electrostatic chuck E by the release voltage.

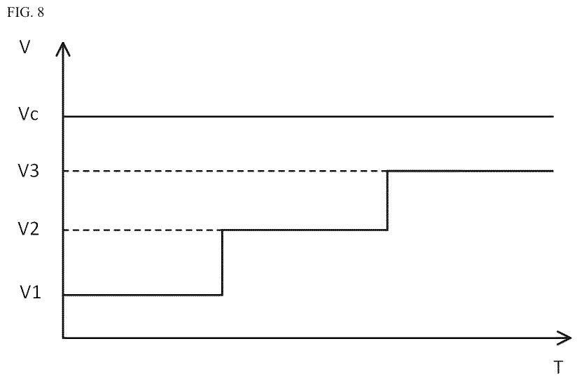

Therefore, it is advantageous to apply a small release voltage in the initial stage and increase the value of the release voltage in steps of V1, V2, and V3 as time passes, as shown in FIG. 8. In this case, the release voltage should not exceed the adsorption voltage Vc during substrate processing, considering the possibility of re-adsorption mentioned above.

As the release voltage is changed, the load on the detachment device F is continuously measured. The control device C continuously monitors the load on the detachment device F at this time. This configuration makes it possible to release the substrate W from the electrostatic chuck E at an appropriate timing. The magnitude of the set value of the release voltage that is set can be changed in steps as shown in FIG. 8, or it can be changed linearly or curvilinearly.

Since the set value of the release voltage that is set may be changed, it is not mandatory to release the substrate W from the electrostatic chuck E by the initial operation of pushing the edge of the substrate W against the claw N1. By changing the set value of the release voltage, the residual adsorption force may be gradually reduced, and the force to press the edge of the substrate W against the claw N1 can be reduced. As a result, the risk of damage to the substrate W in the substrate release operation can be further reduced.

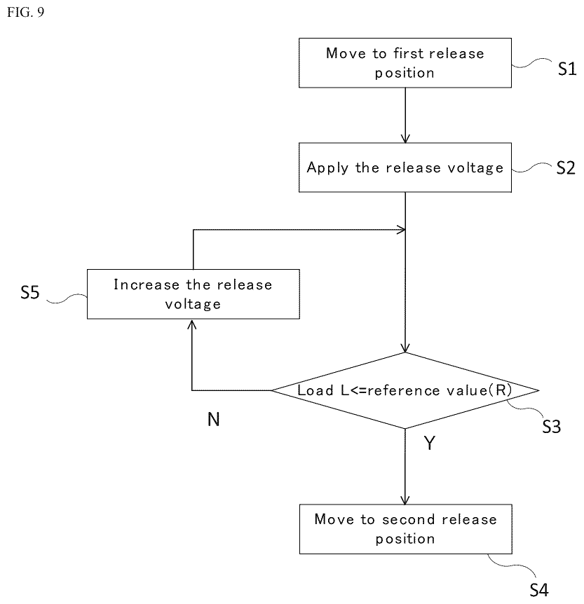

FIG. 9 shows a flowchart illustrating a substrate release method, according to some embodiments. The flowchart will be described with reference to the substrate release apparatus WD described with respect to FIGS. 4-7, by way of example. After the end of substrate processing, the platen 2 moves to a first release position (operation S1). For example, in an embodiment, the platen 2 moves downward and the vacuum hand V1 (V2) swivels, and the platen 2 then rotates clockwise and the edge of the substrate W is pressed against the claw N1 to achieve the position of the substrate W in the first release position.

A release voltage is applied (operation S2). For example, in an embodiment, with the rotational torque of the drive source D2 kept constant and the edge of the substrate W pressed against the claw N1, the release voltage is applied to the electrostatic chuck E.

The load L to the drive source D2 when the release voltage is applied is compared with a reference value R (operation S3). If the load L is less than or equal to the reference value R (operation S3, Y), it is determined that the adsorption state of the substrate W satisfies the reference state, and the substrate W is moved to a second release position (operation S4). For example, in an embodiment, the substrate W is released from the electrostatic chuck E, and the platen 2 is moved further downward and the substrate W is placed on the claws N1 and N2 to achieve the second release position.

On the other hand, if the load L exceeds the reference value R (operation S3, N), the adsorption state is determined to not satisfy the reference state, and the value of the release voltage is increased (operation S5). After increasing the release voltage, the load L on the drive source D2 is measured and the measured value is compared again with the reference value R (operation S3). Operations S5 and S3 are repeated until the condition of operation S3 are satisfied.

The measurement of the load to the drive source D2 may be performed continuously until the adsorption state of the substrate W satisfies the reference state, and the substrate W is moved from the first release position to the second release position. By continuously monitoring the load to the drive source D2, it is possible to determine that the substrate W has been transferred to the second release position as well as the adsorption state of the substrate W.

In the related art technology, the release of the substrate W may be performed by a push-up pin. In this case, a force sensor may be provided on the push-up pin to determine the adsorption state of substrate W by measuring the load of the substrate W on the push-up pin.

However, such a configuration requires a separate force sensor, which incurs additional costs. In addition, maintenance of the force sensor is required in the event of its failure. Considering these points, it is advantageous to measure the load to the drive source originally provided as a device configuration and used for substrate transfer to determine the state of substrate W adsorption.

In the above embodiments, the load to the drive source D2 is measured to determine the adsorption state of the substrate W. However, embodiments are not limited to this configuration, and in an embodiment, the state of substrate W adsorption may be determined by measuring the load to another drive source.

For example, the state of substrate W adsorption may be determined by measuring a load to the drive source D1 for moving the drive shaft 12 up and down. In this case, when the platen 2 is in the state shown in FIG. 4 or FIG. 6, the drive shaft 12 is moved downward by the drive source D1 to release the substrate W from the electrostatic chuck E. In this case, rotation of the platen 2 by the drive source D2 is not be performed.

In the above embodiments, the configuration of an ion implanter is described as an example of a substrate processing apparatus WD, but in various embodiments, the substrate processing apparatus WD can be applied to other semiconductor manufacturing apparatuses such as a film deposition apparatus and a dry etching apparatus.

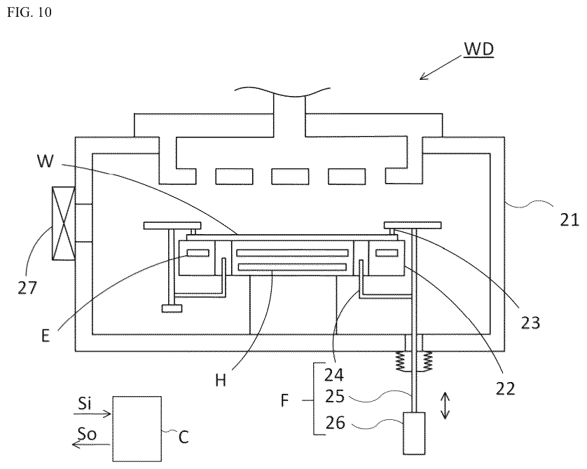

FIG. 10 shows an example configuration of a deposition apparatus. In a process chamber 21, a substrate W is placed on a platen 22. The platen 22 is equipped with an electrostatic chuck E and a heater H. A ring clamp 23 presses the upper end of the substrate W against the platen 22. The deposition process on the substrate W is performed by irradiating plasma from above the substrate W.

The ring clamp 23 is connected to a drive shaft 25. The drive shaft 25 moves up and down in the direction of the arrow in the figure by a drive source 26. An L-shaped lift pin 24 is connected to the drive shaft 25. In FIG. 10, the ring clamp 23 and the lift pin 24 are each depicted on the left and right, but it will be understood that the ring clamp 23 and the lift pin 24 are connected to the drive shaft 25 and move up and down in conjunction with the vertical movement of the drive shaft 25.

After processing the substrate W is completed, the drive shaft 25 moves upward to release the clamping of the substrate W by the ring clamp 23. As the drive shaft 25 continues to move upward, the tip of the lift pin 24 contacts the back surface of the substrate W and a load is applied to the drive source 26 by the substrate W.

The load generated is transmitted to the control device C as the signal Si. As in the above embodiments, the control device C compares the load applied to the drive source 26 with the reference value stored in the control device C.

From the comparison results, if the load exceeds the reference value, the control device C outputs the signal So to increase the set value of the release voltage.

If the load applied to the drive source 26 is less than or equal to the reference value based on the comparison result by the control device C, the lift pin 24 is moved upward to release the substrate W from the electrostatic chuck E. After that, a valve 27 is opened to introduce a hand of the transfer robot into the process chamber 21 to transfer the processed substrate W from the lift pin 24 to outside the process chamber 21. In the deposition apparatus shown the embodiment illustrated in FIG. 10, the detachment device F includes a lift pin 24, a drive shaft 25, and a drive source 26.

Although the above embodiments are described for high-temperature processing in which large warping occurs in the substrate W, the above embodiments may be applied to substrate release operations performed after substrate processing at room temperature.

In some embodiments, the method of determining the adsorption state may be switched according to the temperature of the substrate processing. If the temperature of the substrate processing is high, the configuration described in FIGS. 1-10 may be used to determine the adsorption state of the substrate based on the load on the detachment device F. If the temperature of the substrate processing is room temperature, the adsorption state of the substrate may be determined by measuring an electrostatic capacitance.

If the substrate processing temperature is room temperature, no significant warping occurs in the substrate W. Therefore, the adsorption state of the substrate can be accurately determined even by measuring the electrostatic capacitance.

In some embodiments, the adsorption state of the substrate may be first determined by measuring the electrostatic capacitance, and if the determination is not possible because the measured value is an abnormal value or if the substrate is determined not to be adsorbed by the electrostatic chuck E, the adsorption state of the substrate may be determined based on the load on the detachment device F.

It should be understood that embodiments are not limited to the various embodiments described above, but various other changes and modifications may be made therein without departing from the spirit and scope thereof as set forth in appended claims.

What is claimed is:

1. A substrate processing apparatus comprising:
an electrostatic chuck that is configured to support a substrate;
a detachment device that is configured to release the substrate that is supported by the electrostatic chuck, from the electrostatic chuck; and
a control device that determines a load on the detachment device and applies a release voltage to the electrostatic chuck, based on the load.

2. The substrate processing apparatus according to claim 1,
wherein the control device changes the release voltage to a larger voltage, based on the load being greater than a reference value.

3. The substrate processing apparatus according to claim 2,
wherein the control device changes the release voltage stepwise.

4. The substrate processing apparatus according to claim 2,
wherein the control device monitors the load on the detachment device before the release voltage is changed and monitors the load after the release voltage is changed.

5. The substrate processing apparatus according to claim 4,
wherein the control device detects that the substrate has been released from the electrostatic chuck, based on the monitoring of the load.

6. The substrate processing apparatus according to claim 1,
wherein the release voltage is less than an adsorption voltage applied to the electrostatic chuck during processing of the substrate.

7. The substrate processing apparatus according to claim 1,
wherein the detachment device comprises a drive source that is configured to move the electrostatic chuck during processing of the substrate.

8. The substrate processing apparatus according to claim 7,
wherein the load is based on an output signal of the drive source.

9. The substrate processing apparatus according to claim 7,
wherein the drive source moves the electrostatic chuck up and down, and
wherein the load is based on an output current of the drive source.

10. The substrate processing apparatus according to claim 7,
wherein the drive source rotates the electrostatic chuck, and
wherein the load is based on an output current of the drive source.

11. The substrate processing apparatus according to claim 1,
wherein the detachment device comprises a lift pin that pushes against the substrate.

12. The substrate processing apparatus according to claim 11,
wherein the load based on a pressure applied to the lift pin.

13. The substrate processing apparatus according to claim 1,
wherein the electrostatic chuck comprises a heater, and
wherein the heater heats the substrate to a processing temperature that is higher than room temperature.

14. The substrate processing apparatus according to claim 1,
wherein the control device determines the load on the detachment device after a time period has elapsed.

15. The substrate processing apparatus according to claim 1,
wherein the substrate is a semiconductor wafer.

16. The substrate processing apparatus according to claim 15,
wherein the semiconductor wafer is one of silicon carbide, gallium nitride, or gallium (III) oxide.

17. A substrate processing apparatus comprising:
an electrostatic chuck that is configured to support a substrate;
a control device that applies a release voltage to the electrostatic chuck; and
a drive source that is configured to rotate the electrostatic chuck to release the substrate that is supported by the electrostatic chuck, from the electrostatic chuck,
wherein the control device determines a load on the drive source based on an output signal from the drive source, determines whether the load is greater than a reference value, and when the load is greater than the reference value, increases the release voltage.

18. The substrate processing apparatus according to claim 17,
wherein the control device determines the load at a time at which a torque of the drive source has become constant.

19. A substrate processing apparatus comprising:
a platen comprising an electrostatic chuck that is configured to support a substrate;
a drive source that is configured to move the platen,
a control device that applies a release voltage to the electrostatic chuck and controls the drive source to move the platen to physically release the substrate that is supported by the electrostatic chuck, from the electrostatic chuck; and
wherein the control device determines a load caused by a movement of the platen to physically release the substrate, determines whether the load is greater than a reference value, and when the load is greater than the reference value, increases the release voltage.

20. The substrate processing apparatus according to claim 19, wherein the load is based on an output current of the drive source.
